(19) United States
(12) Patent Application Publication
(10) Pub. No.: US 2024/0088620 A1
(43) Pub. Date: Mar. 14, 2024

(54) SEMICONDUCTOR LASER MODULE AND LASER MACHINING APPARATUS

(71) Applicant: Mitsubishi Electric Corporation, Chiyoda-ku, Tokyo (JP)

(72) Inventors: Yuki OKAMOTO, Tokyo (JP); Daisuke MORITA, Tokyo (JP)

(73) Assignee: Mitsubishi Electric Corporation, Chiyoda-ku, Tokyo (JP)

(21) Appl. No.: 18/264,257

(22) PCT Filed: Apr. 4, 2022
(86) PCT No.: PCT/JP2022/017056

§ 371 Date: Aug. 4, 2023

(30) Foreign Application Priority Data
Apr. 13, 2021 (JP) 2021-067920

(51) Int. Cl. H01S 5/024; B23K 26/06; B23K 26/70; H01S 5/023; H01S 5/0233

(52) U.S. Cl. CPC H01S 5/02476; B23K 26/0604; B23K 26/703; H01S 5/023; H01S 5/0233; H01S 5/02423

(57) ABSTRACT

A semiconductor laser module includes a heat sink, a first electrode disposed in a first region of the heat sink, an electrically insulating layer disposed on the first electrode, a submount that is disposed in a second region of the heat sink and is electrically conductive and thermally conductive, a laser diode element that is disposed on the submount and emits a laser beam, a feed structure that is disposed on the laser diode element and is electrically conductive, thermally conductive, and elastic, and a second electrode disposed on and in contact with the electrically insulating layer and the feed structure. The second electrode includes an electrode-facing portion having a flat surface in contact with the electrically insulating layer, and a protruding portion having a flat surface in contact with the feed structure, and protruding toward the heat sink with respect to the electrode-facing portion.

### FIELD

The present disclosure relates to a semiconductor laser module that outputs a laser beam, and to a laser machining apparatus.

### BACKGROUND

A high power laser device, a typical example of which is a light source for a laser machining apparatus, optically combines light beams generated by multiple semiconductor laser modules to achieve a high power light beam. Higher output power is achieved by either use of a larger number of semiconductor laser modules or output of higher power per semiconductor laser module. Use of a larger number of semiconductor laser modules results in a larger size of the laser device. It is therefore desirable to output higher power per semiconductor laser module. Outputting higher power by a semiconductor laser module involves a higher amount of heat generation, and thus presents issues in output characteristic and in long-term reliability in view of increase in the operation temperature of the laser diode element. Thus, a semiconductor laser module structure that provides high heat dissipation performance has been developed.

Patent Literature 1 discloses a semiconductor laser module including a stacked body including a laser diode element and two electrically conductive plates provided respectively in contact with the bottom surface and with the top surface of the laser diode element; two electrode units that sandwich therebetween the stacked body; and an electrically insulating plate in a region where the stacked body is not disposed, of a region sandwiched by the two electrode units, where the two electrode units are held by holding means. In the semiconductor laser module described in Patent Literature 1, the electrically conductive plates each have multiple protruding portions, and the stacked body has a thickness greater than the thickness of the electrically insulating plate. This causes the protruding portions of the electrically conductive plates to be deformed thereby to increase the area of contact between the electrically conductive plates and corresponding ones of the electrode units and the laser diode element. Electrical conductivity and heat dissipation capability are thus increased.

### CITATION LIST

### Patent Literature

Patent Literature 1: Japanese Patent No. 6472683

### SUMMARY OF INVENTION

### Problem to be Solved by the Invention

Meanwhile, a design change of a semiconductor laser module may involve a change in the thickness of the laser diode element. A change in the thickness of the laser diode element in the semiconductor laser module described in Patent Literature 1 requires a change in the thickness of the electrically insulating plate or a change in the thickness and the shape of the electrically conductive plates. However, the semiconductor laser module described in Patent Literature 1 has a fixed thickness of the electrically insulating plate or fixed thickness and shape of the electrically conductive plates to provide an optimum heat dissipation capability in association with the thickness of the semiconductor laser element. A change in one of the electrically insulating plate and the electrically conductive plates will result in a reduction in the heat dissipation capability. That is, the semiconductor laser module described in Patent Literature 1 needs determination of the thickness of the electrically insulating plate and the thickness and the shape of the electrically conductive plates to optimize the heat dissipation capability of the laser diode element that has been changed in thickness. This process requires time. That is, the semiconductor laser module described in Patent Literature 1 suffers from a problem in failing to address a design change of the laser diode element.

The present disclosure has been made in view of the foregoing, and it is an object of the present disclosure to provide a semiconductor laser module capable of maintaining the heat dissipation capability to a heat dissipation capability equivalent to that of before the change was made without changing an electrically insulating plate or an electrically conductive plate even when a design change has caused a change in the thickness of the laser diode element.

### Means to Solve the Problem

To solve the problem and achieve the object described above, a semiconductor laser module according to the present disclosure includes a heat sink, a first electrode, an electrically insulating layer, a submount, a laser diode element, a feed structure, and a second electrode. The first electrode is disposed in a first region of the heat sink. The electrically insulating layer is disposed on the first electrode. The submount is electrically conductive and thermally conductive, and is disposed in a second region different from the first region, of the heat sink. The laser diode element is disposed on the submount, and emits a laser beam. The feed structure is electrically conductive, thermally conductive, and elastic, and is disposed on the laser diode element. The second electrode is disposed on and in contact with the electrically insulating layer and the feed structure. The second electrode includes an electrode-facing portion having a flat surface in contact with the electrically insulating layer, and a protruding portion having a flat surface in contact with the feed structure and protruding toward the heat sink with respect to the electrode-facing portion.

### Effects of the Invention

The present disclosure is advantageous in capability of maintaining the heat dissipation capability to a heat dissipation capability equivalent to that of before the change was made without changing an electrically insulating plate or an electrically conductive plate even when a design change has caused a change in the thickness of the laser diode element.

### BRIEF DESCRIPTION OF DRAWINGS

FIG. 1 is a perspective view schematically illustrating an example of configuration of a semiconductor laser module according to a first embodiment.

FIG. 2 is a partial cross-sectional view schematically illustrating an example of configuration of the semiconductor laser module according to the first embodiment.

FIG. 3 is a front view schematically illustrating an example of configuration of the semiconductor laser module according to the first embodiment.

FIG. 4 is a cross-sectional view schematically illustrating an example of configuration in the vicinity of a laser diode element of the semiconductor laser module according to the first embodiment.

FIG. 5 is a diagram schematically illustrating a process of heat diffusion in a cathode electrode of the semiconductor laser module according to the first embodiment.

FIG. 6 is a diagram illustrating an example of configuration of a feed structure of the semiconductor laser module according to the first embodiment.

FIG. 7 is a diagram illustrating an example of shape of a ribbon before assembly of the semiconductor laser module according to the first embodiment.

FIG. 8 is a diagram illustrating an example of shape of the ribbon after assembly of the semiconductor laser module according to the first embodiment.

FIG. 9 is a diagram illustrating an example of shape of the ribbon after assembly of the semiconductor laser module according to the first embodiment.

FIG. 10 is a diagram illustrating an example of configuration of the feed structure of the semiconductor laser module according to the first embodiment.

FIG. 11 is a diagram schematically illustrating an example of configuration of a laser machining apparatus according to the first embodiment.

FIG. 12 is a diagram schematically illustrating an example of configuration of a laser oscillator for use in the laser machining apparatus according to the first

### DESCRIPTION OF EMBODIMENT

A semiconductor laser module and a laser machining apparatus according to embodiments of the present disclosure will be described in detail below with reference to the drawings.

### First Embodiment

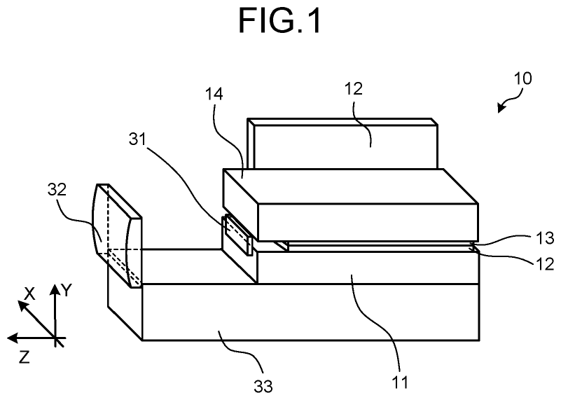

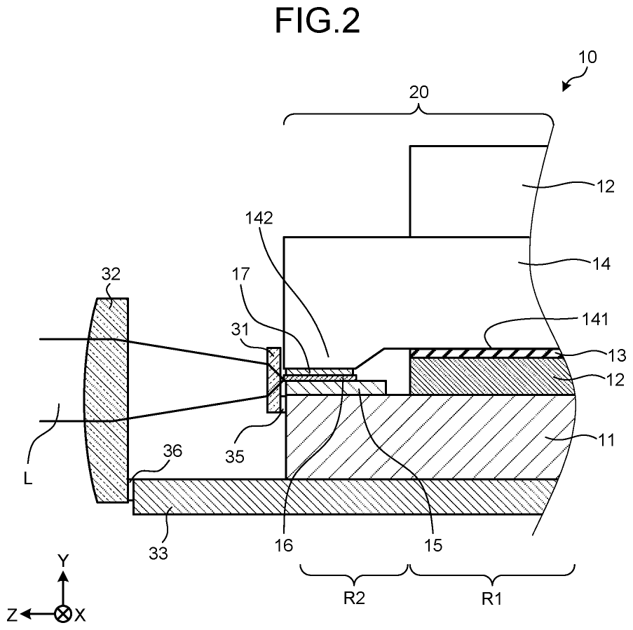

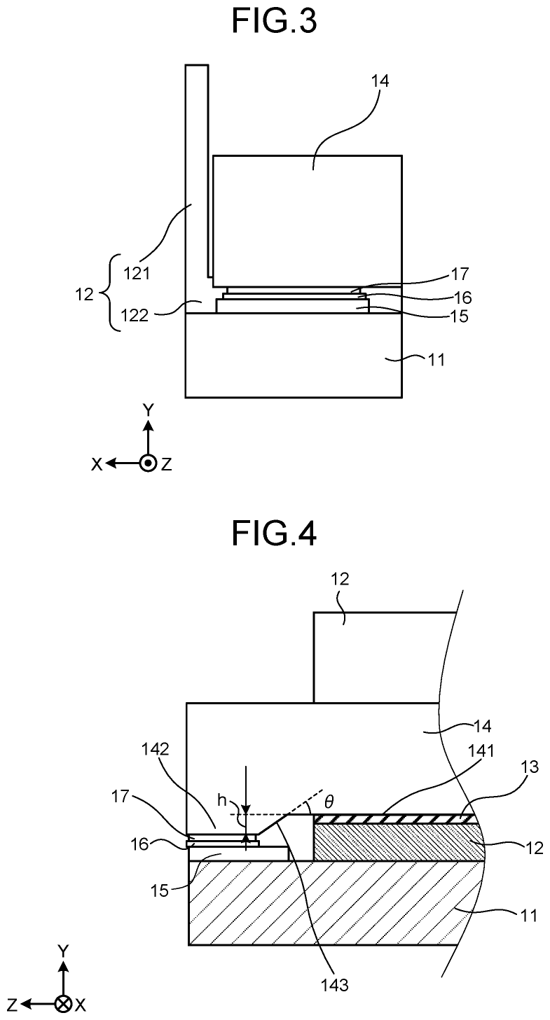

FIG. 1 is a perspective view schematically illustrating an example of configuration of a semiconductor laser module according to a first embodiment. FIG. 2 is a partial cross-sectional view schematically illustrating an example of configuration of the semiconductor laser module according to the first embodiment. FIG. 3 is a front view schematically illustrating an example of configuration of the semiconductor laser module according to the first embodiment. The following description assumes that a direction in which a laser beam L is emitted is defined as a Z-axis direction; a direction which is perpendicular to Z-axis and in which members forming a semiconductor laser module 10 are stacked one on top of another is defined as a Y-axis direction; and a direction perpendicular to both Z-axis and Y-axis is defined as an X-axis direction. A relative relationship between two positions along the Y-axis direction is hereinafter expressed in terms of upward and downward directions. In addition, it is assumed that the face on the side on which a laser diode element 16 is disposed, perpendicular to the Z-axis direction, is the front face. The cross section of FIG. 2 corresponds to a YZ-cross section of FIG. 1. Moreover, FIG. 3 illustrates a front view without a slow-axis collimator (SAC) 32.

The semiconductor laser module 10 includes a heat sink 11, an anode electrode 12, an electrically insulating sheet 13, a cathode electrode 14, a submount 15, a laser diode element 16, and a feed structure 17.

The heat sink 11 is a heat dissipating member for reducing an increase in temperature of the laser diode element 16. The heat sink 11 has a flat plate-shaped structure extending in the Z-axis direction. The heat sink 11 is formed of a highly thermally conductive material. The heat sink 11 is herein also formed of an electrically conductive material. In one example, the heat sink 11 is formed of copper (Cu). Further in one example, the heat sink 11 includes therein a water channel for allowing cooling water to flow therethrough. The heat sink 11 has a top surface having an electrode disposition region R1 corresponding to a first region, and an element disposition region R2 corresponding to a second region.

The anode electrode 12, having an L shape in an XY-plane, is disposed in the electrode disposition region R1 of the heat sink 11. The anode electrode 12 is formed using an L-shaped member having a first portion 121 having a plate shape parallel to a YZ-plane, and a second portion 122 having a plate shape parallel to a ZX-plane. The anode electrode 12 is an electrode connected to a portion on the P-type semiconductor side of the laser diode element 16. The anode electrode 12 is connected to a power supply (not illustrated) to supply current to the laser diode element 16. The anode electrode 12 and the heat sink 11 are electrically connected to each other. The anode electrode 12 is formed of copper in one example. The anode electrode 12 corresponds to a first electrode.

The cathode electrode 14 is disposed on the second portion 122 of the anode electrode 12 with the electrically insulating sheet 13 interposed therebetween. The cathode electrode 14 has a shape and a size almost similar to the shape and the size of the heat sink 11 in a ZX-plane. That is, the cathode electrode 14 has a structure protruding with respect to the anode electrode 12 in the Z-axis direction in a ZX-plane. The cathode electrode 14 is disposed spaced apart from, and out of contact with, the first portion 121 of the anode electrode 12 in the X-direction. The cathode electrode 14 is an electrode connected to a power supply (not illustrated) to supply current to the laser diode element 16. The cathode electrode 14 is connected to a portion on the N-type semiconductor side of the laser diode element 16. The cathode electrode 14 also functions to dissipate heat generated in the laser diode element 16. The cathode electrode 14 is formed of copper having a gold-plated surface in one example. The cathode electrode 14 corresponds to a second electrode.

The electrically insulating sheet 13 is an electrically insulating layer disposed on the second portion 122 of the anode electrode 12, and provided for insulation between the anode electrode 12 and the cathode electrode 14.

The laser diode element 16 is disposed in the element disposition region R2 of the heat sink 11 with the submount 15 interposed therebetween. The submount 15 is fixed on the element disposition region R2 of the heat sink 11. The submount 15 is an intermediate member for relieving stress generated in the laser diode element 16 due to a difference of linear expansion coefficient between the heat sink 11 and the laser diode element 16. That is, the submount 15 desirably has a linear expansion coefficient between the linear expansion coefficient of the laser diode element 16 and the linear expansion coefficient of the heat sink 11. The submount 15 is desirably also thermally conductive to conduct heat from the laser diode element 16 to the heat sink 11, and also electrically conductive to provide electrical connection with the anode electrode 12 via the heat sink 11. The submount 15 is formed of copper-tungsten (CuW) or aluminum nitride (AlN) in one example.

The laser diode element 16 is disposed and fixed on the submount 15. The laser diode element 16 is an edge emitting laser including a PN junction parallel to a ZX-plane to emit the laser beam L in the Z-axis direction. In the laser diode element 16, gallium arsenide (GaAs) is used for the substrate, and indium gallium arsenide (InGaAs) is used for the active layer in one example. The laser diode element 16 is disposed such that the edge face in the Z-axis direction thereof is almost aligned with the position, in the Z-axis direction, of the edge faces of the heat sink 11 and of the cathode electrode 14.

The feed structure 17 is disposed on the laser diode element 16. The feed structure 17 electrically connects the laser diode element 16 and the cathode electrode 14 to each other, and has a contact arrangement having a sufficiently large area of contact with the laser diode element 16 to function to improve the amount of heat dissipation from the top surface of the laser diode element 16.

An upper portion of the element disposition region R2 of the heat sink 11 is covered by the cathode electrode 14. The submount 15, the laser diode element 16, and the feed structure 17 are disposed in a space formed between the heat sink 11 and the cathode electrode 14.

The anode electrode 12 is electrically connected to the laser diode element 16 via the heat sink 11 and via the submount 15. The cathode electrode 14 is electrically connected to the laser diode element 16 via the feed structure 17.

Note that the foregoing description assumes that the heat sink 11 is electrically conductive, but the heat sink 11 may partially include an electrically insulating layer. This can be achieved by either use of an electrically conductive material in an upper portion of the heat sink 11, or disposition of an electrically conductive material between the heat sink 11 and the anode electrode 12 and between the heat sink 11 and the submount 15.

A structure unit for emitting the laser beam L including the heat sink 11, the anode electrode 12, the electrically insulating sheet 13, the cathode electrode 14, the submount 15, the laser diode element 16, and the feed structure 17 is hereinafter referred to as laser emission unit 20.

The semiconductor laser module 10 also includes a fast-axis collimator (FAC) 31, the SAC 32, and a manifold 33.

The FAC 31 is an optical component disposed on the edge face in the Z-axis direction, of the laser diode element 16 of the laser emission unit 20 to collimate a fast-axis direction component of the laser beam L emitted from the laser diode element 16. In one example, the FAC 31 is fixed on the edge face in the Z-axis direction, of the heat sink 11 using adhesive 35.

The SAC 32 is an optical component to collimate a slow-axis direction component of the laser beam L that has passed through the FAC 31. The SAC 32 is disposed spaced apart from the FAC 31.

The manifold 33 serves as a base member of the semiconductor laser module 10, and is fixed to the housing of the laser machining apparatus. The manifold 33 supports and fixes the heat sink 11, more specifically, the laser emission unit 20, on the top surface of the manifold 33. The manifold 33 also serves a relay member including a water channel to lead cooling water to the heat sink 11. The manifold 33 includes therein the water channel to lead cooling water to the heat sink 11. The water channel is connected to the water channel provided in the heat sink 11 using a connecting member. The manifold 33 is formed of steel use stainless (SUS) 303 in one example.

The manifold 33 has an edge portion in the Z-axis direction, protruding in the direction of emission of the laser beam L with respect to the edge portion in the Z-axis direction, of the laser emission unit 20 on the manifold 33. The SAC 32 is fixed to this edge portion using adhesive 36. Note that FIG. 1 illustrates an example in which the laser emission unit 20, the FAC 31, and the SAC 32 are integrated with one another on the manifold 33, but the SAC 32 may be provided separately from the laser emission unit 20 and from the FAC 31.

The structure of the cathode electrode 14 will next be described in more detail. FIG. 4 is a cross-sectional view schematically illustrating an example of configuration in the vicinity of the laser diode element of the semiconductor laser module according to the first embodiment. In the first embodiment, the cathode electrode 14 has an electrode-facing portion 141 having a flat surface facing the anode electrode 12 and a protruding portion 142 having a flat surface facing the laser diode element 16 and protruding toward the heat sink 11 with respect to the electrode-facing portion 141, on the bottom surface of the cathode electrode 14, which surface is the surface on the side nearer to the heat sink 11.

When the cathode electrode 14 has not yet been placed, the value obtained by subtraction of a height h of the protruding portion 142 from the sum of the thicknesses of the electrically insulating sheet 13 and of the anode electrode 12 is less than the sum of the thicknesses of the submount 15, of the laser diode element 16, and of the feed structure 17. This allows the feed structure 17 to be elastically deformed to increase the area of contact between the laser diode element 16 and the feed structure 17 when the cathode electrode 14 is disposed to form the structure of the laser emission unit 20. This then enables improvement in the amount of heat dissipation from the laser diode element 16 to the cathode electrode 14.

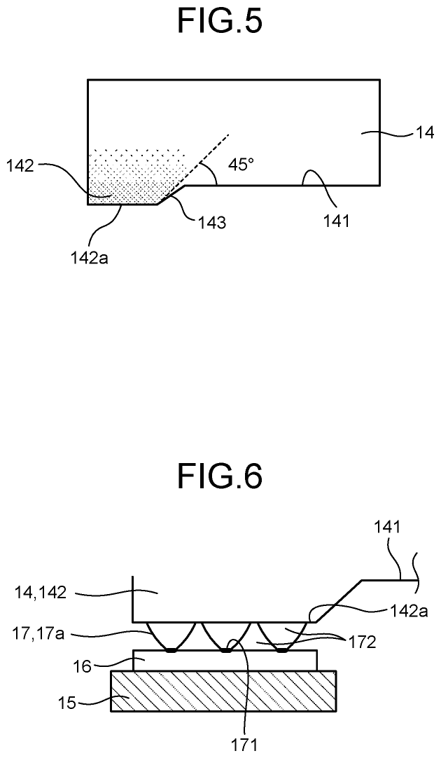

In addition, a side surface 143 connecting to the electrode-facing portion 141, among the side surfaces forming the protruding portion 142, intersects the surface forming the electrode-facing portion 141 at an angle θ less than or equal to 45°. FIG. 5 is a diagram schematically illustrating a process of heat diffusion in the cathode electrode of the semiconductor laser module according to the first embodiment. It is known that when the cathode electrode 14 is formed of an isotropic substance, and a flat surface 142a of the protruding portion 142 is in contact with a heat source, heat in the isotropic substance diffuses along a plane at an angle of 45° with respect to the flat surface 142a in contact with the heat source, from peripheries of the surface in contact with the heat source. Use of an angle θ greater than 45° accordingly impedes this diffusion of heat due to the side surface 143, thereby reducing the heat releasing capability as compared to when the angle θ is 45°. In contrast, use of an angle θ less than 45° causes heat to diffuse in a portion inside the side surface 143, thereby enabling a heat releasing capability to be achieved that is similar to the heat releasing capability when the angle θ is 45°. Note that an angle θ of 0° corresponds to a case in which the protruding portion 142 is not included. The protruding portion 142 is an essential component in the first embodiment, meaning that the angle θ is greater than 0°.

As described above, providing the protruding portion 142 in the cathode electrode 14 and providing the feed structure 17 that can be elastically deformed allows heat generated in the laser diode element 16 to effectively diffuse into the cathode electrode 14.

A structure of the feed structure 17 will now be described. The feed structure 17 according to the first embodiment desirably satisfies the following four requirements.

(1) In a heat cycle involving switching between an electrically conducting state and an electrically non-conducting state of the semiconductor laser module 10, stress occurring in the laser diode element 16 should be sufficiently low.

(2) Should not usually join to gold plate on the surface of the laser diode element 16 at a temperature of about 80° C. in regard to the temperature of the laser diode element 16 in an electrically conducting state.

(3) Should have sufficiently high electrical conductivity.

(4) Should have sufficiently high thermal conductivity.

Note that when the feed structure 17 uses a material such as solder, such material may fuse at a high temperature to join to the gold plate on the surface of the laser diode element 16. When this happens, the feed structure 17 joins to the laser diode element 16 as given in the above item (2), thereby easily causing stress to occur in the joined portion, which prevents the feed structure 17 from satisfying the above requirement (1).

One material for the feed structure 17 that satisfies the above requirements (1) to (4) is an electrically conductive ribbon having a thickness of several tens of micrometers. Examples of the electrically conductive ribbon include a gold ribbon and a copper ribbon. FIG. 6 is a diagram illustrating an example of configuration of the feed structure of the semiconductor laser module according to the first embodiment. FIG. 6 illustrates a situation when the semiconductor laser module has not been completely assembled, that is, a situation in which the cathode electrode 14 has not yet been placed. As illustrated in FIG. 6, an electrically conductive ribbon 17a has a corrugated shape, and is bonded to the protruding portion 142 of the cathode electrode 14. When the semiconductor laser module 10 has not been assembled, the electrically conductive ribbon 17a has a peak portion 171 of the corrugated shape in contact with the top surface of the laser diode element 16. Portions between the electrically conductive ribbon 17a and the laser diode element 16 and portions between the electrically conductive ribbon 17a and the cathode electrode 14 each form a void space 172.

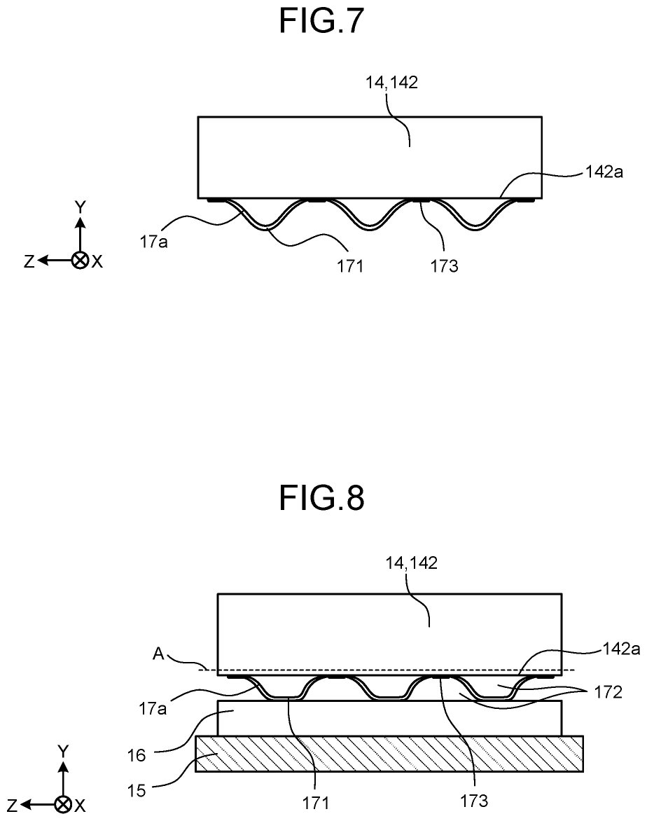

The sizes of the electrically conductive ribbon 17a and of the void space 172 will next be described in detail. FIG. 7 is a diagram illustrating an example of the shape of the ribbon before assembly of the semiconductor laser module according to the first embodiment. As illustrated in FIG. 7, the electrically conductive ribbon 17a has a corrugated shape. Peak portions of the electrically conductive ribbon 17a on the side nearer to the cathode electrode 14 are bonded, at a certain interval, to the flat surface 142a of the protruding portion 142 of the cathode electrode 14. The electrically conductive ribbon 17a is thus fixed to the cathode electrode 14. That is, portions including the peak portions of the electrically conductive ribbon 17a fixed to the flat surface 142a of the cathode electrode 14 each form a bonding portion 173. The bonding portion 173 is fixed to the flat surface 142a using a method of ultrasonic joining or the like in one example.

FIG. 8 is a diagram illustrating an example of the shape of the ribbon after assembly of the semiconductor laser module according to the first embodiment. The void space 172 needs to be sufficiently small in size to obtain a sufficiently large area of contact between the electrically conductive ribbon 17a and the laser diode element 16. In this situation, the peak portions 171 of the corrugated shape of the electrically conductive ribbon 17a on the side nearer to the laser diode element 16 after assembly each have a flat shape as illustrated in FIG. 8 following the shape of the corresponding surface of the laser diode element 16.

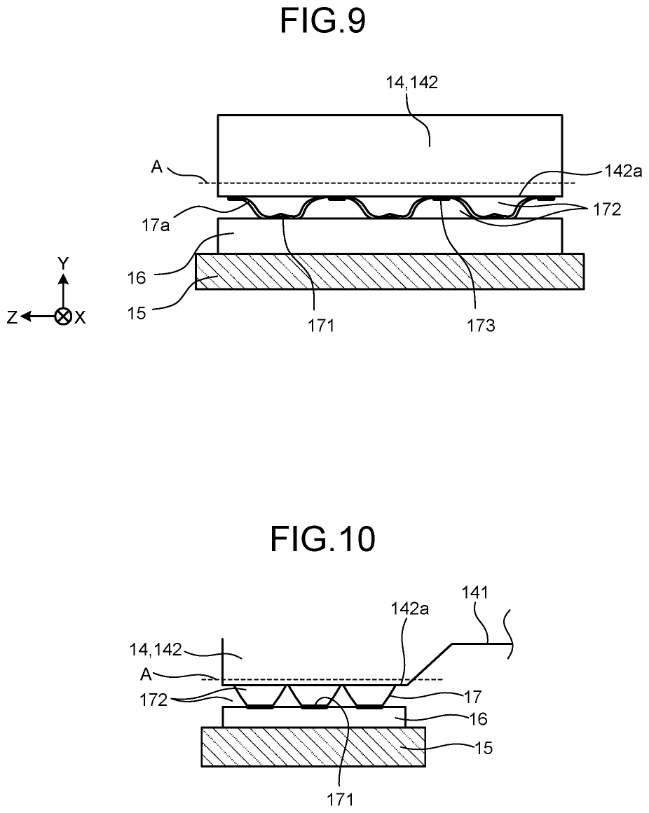

FIG. 9 is a diagram illustrating an example of the shape of the ribbon after assembly of the semiconductor laser module according to the first embodiment. Meanwhile, when the void space 172 becomes excessively small, the electrically conductive ribbon 17a may undergo unexpected deformation as illustrated in FIG. 9, thereby causing a part of the peak portion 171 to be separated apart from the laser diode element 16. This will reduce the area of contact between the electrically conductive ribbon 17a and the laser diode element 16. Accordingly, to allow a sufficiently large area of the peak portion 171 to be deformed into a flat shape without undergoing unexpected deformation, selection of suitable dimension values of the electrically conductive ribbon 17a and of the void space 172 is desirable. To form the shape of the electrically conductive ribbon 17a after assembly as illustrated in FIG. 8, adjacent ones of the bonding portions 173 of the electrically conductive ribbon 17a desirably have a spacing therebetween of about 450 micrometers (μm); the peak portion 171 of the corrugated shape and the flat surface 142a desirably have a distance therebetween in the Y-axis direction of about 150 μm in the pre-assembly state illustrated in FIG. 7; and the void space 172 desirably has a size in the Y-axis direction of about 130 μm in the assembled state illustrated in FIG. 8. Note that the sizes described above are merely by way of example. The sizes may be modified to any value that has been adjusted to cause the electrically conductive ribbon 17a after assembly to have a shape as illustrated in FIG. 8, that is, to cause no part of the peak portion 171 to be separated apart from the laser diode element 16.

As illustrated in FIG. 2, the submount 15, the laser diode element 16, and the feed structure 17 are stacked one on top of another on the element disposition region R2 of the heat sink 11; and the anode electrode 12 and the electrically insulating sheet 13 are stacked one on top of another on the electrode disposition region R1. When the cathode electrode 14 has not yet been placed, the sum of the thicknesses of the submount 15, of the laser diode element 16, and of the feed structure 17 is, as described above, greater than the value obtained by subtraction of the height h of the protruding portion 142 from the sum of the thicknesses of the anode electrode 12 and of the electrically insulating sheet 13.

In this situation, the cathode electrode 14 is placed to cause the electrically conductive ribbon 17a to be elastically deformed according to the thicknesses of the anode electrode 12 and of the electrically insulating sheet 13 in the electrode disposition region R1. FIG. 10 is a diagram illustrating an example of configuration of the feed structure of the semiconductor laser module according to the first embodiment. FIG. 10 illustrates a situation in which the semiconductor laser module 10 has been assembled. As illustrated in FIG. 10, the peak portion 171 of the electrically conductive ribbon 17a on the side nearer to the laser diode element 16 collapses. The broken line A in FIG. 10 represents the position of the flat surface 142a to be bonded to the electrically conductive ribbon 17a, of the protruding portion 142 of the cathode electrode 14 in FIG. 6. After the semiconductor laser module 10 has been assembled, collapse of the electrically conductive ribbon 17a makes the sum of the thicknesses of the submount 15, of the laser diode element 16, and of the feed structure 17 become equal to the value obtained by subtraction of the height h of the protruding portion 142 from the sum of the thicknesses of the anode electrode 12 and of the electrically insulating sheet 13.

In addition, collapse of the electrically conductive ribbon 17a increases the area of contact between the electrically conductive ribbon 17a and the laser diode element 16. This allows heat generated in the laser diode element 16 to conduct to the cathode electrode 14 via the electrically conductive ribbon 17a. Heat conducted to the cathode electrode 14 diffuses from the portion in contact with the electrically conductive ribbon 17a into the cathode electrode 14 along a plane at an angle of 45° as illustrated in FIG. 5, transfers through the electrically insulating sheet 13 and the anode electrode 12, and is finally dissipated to the heat sink 11. Heat from the laser diode element 16 is thus dissipated.

Note that a higher degree of elastic deformation of the electrically conductive ribbon 17a will result in a smaller void space 172 between the electrically conductive ribbon 17a and the laser diode element 16 in FIG. 10, thereby causing more stress to be exerted on the laser diode element 16. The above requirement (1) will thus be unsatisfied. Stress becomes less likely to occur on the contact point by maintaining the electrically conductive ribbon 17a in contact with the laser diode element 16 as illustrated in FIG. 10 without allowing the electrically conductive ribbon 17a to be fully joined to the laser diode element 16. Thus, the height h of the protruding portion 142 of the cathode electrode 14, the thickness of the anode electrode 12, and the thickness of the electrically insulating sheet 13 are managed to avoid elimination of the void space 172 between the electrically conductive ribbon 17a and the laser diode element 16 and elimination of the void space 172 between the electrically conductive ribbon 17a and the cathode electrode 14. Capability of heat release to the cathode electrode 14 via the electrically conductive ribbon 17a can be improved without occurrence of stress between the electrically conductive ribbon 17a and the laser diode element 16 by management to keep the distance between the flat surface 142a of the protruding portion 142 of the cathode electrode 14 and the top surface of the heat sink 11 in a range from 50 μm to 100 μm with the semiconductor laser module 10 assembled.

A case will next be described in which a design change involves a change in the thickness of the laser diode element 16 in the semiconductor laser module 10 according to the first embodiment. The technology of Patent Literature 1 requires a change in at least one of the thickness of the electrically insulating member and the thickness of the electrically conductive member under a condition where heat dissipation capability has been optimized for the thickness of the laser diode element before the design change. In contrast, the semiconductor laser module 10 according to the first embodiment enables such situation to be addressed in most cases, by merely changing the height h of the protruding portion 142 among the height h of the protruding portion 142 of the cathode electrode 14, the thickness of the anode electrode 12, and the thickness of the electrically insulating sheet 13. That is, there is no need to change, in the first embodiment, the thickness of the electrically insulating sheet 13 or the thickness of the feed structure 17. In addition, even when the height h of the protruding portion 142 of the cathode electrode 14 is changed, the heat dissipation capability of the cathode electrode 14 remains unchanged before and after the change of the thickness of the laser diode element 16. Thus, a design change of the semiconductor laser module 10 can be addressed easily.

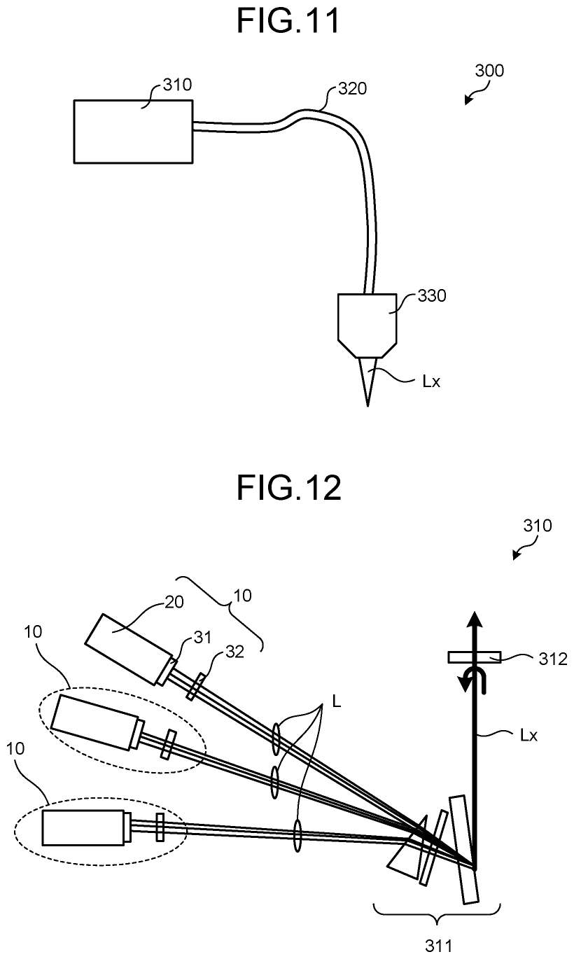

Such semiconductor laser module 10 can be used as a light source of a laser machining apparatus. FIG. 11 is a diagram schematically illustrating an example of configuration of a laser machining apparatus according to the first embodiment. A laser machining apparatus 300 includes a laser oscillator 310, an optical fiber 320, and a machining head 330.

The laser oscillator 310 emits a laser beam. FIG. 12 is a diagram schematically illustrating an example of configuration of a laser oscillator for use in the laser machining apparatus according to the first embodiment. The laser oscillator 310 includes multiple semiconductor laser modules 10, an optical coupler unit 311, and an external resonant mirror 312. The semiconductor laser modules 10 each have a structure capable of providing an improved heat releasing capability as described above. The optical coupler unit 311 couples together the laser beams L from the multiple semiconductor laser modules 10. Examples of the optical coupler unit 311 include a prism and a diffraction grating. The external resonant mirror 312 transmits part of a laser beam Lx generated by coupling in the optical coupler unit 311, and reflects the remaining part toward the semiconductor laser modules 10. The external resonant mirror 312 forms an optical resonator with the surfaces for emission of the laser beams L in the laser diode elements 16 of the semiconductor laser modules 10.

Returning to the description with reference to FIG. 11, the optical fiber 320 transmits the laser beam Lx generated by coupling in the laser oscillator 310 and emitted from the laser oscillator 310 to the machining head 330.

The machining head 330 collects the laser beam Lx propagated through the optical fiber 320, and emits the laser beam Lx to a workpiece. The machining head 330 includes a light collecting optical system that collects the laser beam Lx propagated through the optical fiber 320, and emits the laser beam Lx to a workpiece. During machining, the machining head 330 is positioned to face the position where machining is to be performed, of the workpiece.

The semiconductor laser module 10 of the first embodiment includes the anode electrode 12 disposed on the electrode disposition region R1 of the heat sink 11, and the cathode electrode 14 disposed with the electrically insulating sheet 13 interposed therebetween. The submount 15, the laser diode element 16, and the feed structure 17, which is formed of an elastically deformable material, are sequentially stacked one on top of another on the element disposition region R2 of the heat sink 11. The cathode electrode 14 is disposed to cover the electrically insulating sheet 13 on the electrode disposition region R1, and the feed structure 17 on the element disposition region R2. The cathode electrode 14 has the protruding portion 142 protruding downward in the element disposition region R2 with respect to the surface in the electrode disposition region R1. When the cathode electrode 14 has not yet been placed, the value obtained by subtraction of the height h of the protruding portion 142 from the thicknesses of the electrically insulating sheet 13 and of the anode electrode 12 is less than the sum of the thicknesses of the submount 15, of the laser diode element 16, and of the feed structure 17. In addition, the side surface 143 connected to the electrode disposition region R1, of the protruding portion 142, is disposed to form an angle less than or equal to 45° with the flat surface formed in the electrode disposition region R1, of the cathode electrode 14. This allows heat generated in the laser diode element 16 to diffuse from the flat surface 142a in contact with the feed structure 17 into the cathode electrode 14, thereby improves heat dissipation.

Use, as the feed structure 17, of the electrically conductive ribbon 17a, which does not join to the gold plate used on the laser diode element 16, allows the feed structure 17 to be elastically deformed when the semiconductor laser module 10 is assembled. This increases the area of contact between the feed structure 17 and the laser diode element 16, and enables improvement in the amount of heat dissipation from the top surface of the laser diode element 16. The feed structure 17 does not join to the gold plate provided on the top surface of the laser diode element 16, and can therefore reduce the stress occurring on the laser diode element 16 to a sufficient low level. This can reduce or prevent damage to the laser diode element 16 caused by the stress.

In addition, when the thickness of the laser diode element 16 is changed due to a specification change, this change can be addressed without a design change of the members other than the cathode electrode 14 by changing the height h of the protruding portion 142. Moreover, the semiconductor laser module 10 after the change can maintain the heat dissipation capability to a heat dissipation capability equivalent to that of before the change was made.

Furthermore, the laser diode element is merely sandwiched in Patent Literature 1, and is thus difficult of positioning. In contrast, the laser diode element 16 of the first embodiment is fixed on the submount 15, and is accordingly easier of positioning than the laser diode element of Patent Literature 1.

The configurations described in the foregoing embodiment are merely examples. These configurations may be combined with a known other technology, and moreover, part of such configurations may be omitted and/or modified without departing from the spirit thereof.

### REFERENCE SIGNS LIST

10 semiconductor laser module; 11 heat sink; 12 anode electrode; 13 electrically insulating sheet; 14 cathode electrode; 15 submount; 16 laser diode element; 17 feed structure; 17a electrically conductive ribbon; 20 laser emission unit; 31 FAC; 32 SAC; 33 manifold; 35, 36 adhesive; 121 first portion; 122 second portion; 141 electrode-facing portion; 142 protruding portion; 142a flat surface; 143 side surface; 171 peak portion; 172 void space; 173 bonding portion; 300 laser machining apparatus; 310 laser oscillator; 311 optical coupler unit; 312 external resonant mirror; 320 optical fiber; 330 machining head; L, Lx laser beam; R1 electrode disposition region; R2 element disposition region.

1. A semiconductor laser module comprising:
a heat sink;
a first electrode disposed in a first region of the heat sink;
an electrically insulating layer disposed on the first electrode;
a submount being electrically conductive and thermally conductive, disposed in a second region of the heat sink, the second region being different from the first region;
a laser diode element to emit a laser beam, disposed on the submount;
a feed structure being electrically conductive, thermally conductive, and elastic, disposed on the laser diode element;
a second electrode disposed on and in contact with the electrically insulating layer and the feed structure;
a fast-axis collimator to collimate a fast-axis direction component of the laser beam emitted from the laser diode element; and
a slow-axis collimator to collimate a slow-axis direction component of the laser beam emitted from the laser diode element, wherein
the second electrode includes an electrode-facing portion and a protruding portion, the electrode-facing portion having a flat surface in contact with the electrically insulating layer, the protruding portion having a flat surface in contact with the feed structure and protruding toward the heat sink with respect to the electrode-facing portion.

2. The semiconductor laser module according to claim 1, wherein a side surface connecting to the electrode-facing portion, among side surfaces forming the protruding portion, intersects the flat surface of the electrode-facing portion at an angle less than or equal to 45 degrees.

3. The semiconductor laser module according to claim 1, wherein when the second electrode is not placed on the electrically insulating layer or on the feed structure, a value obtained by subtraction of a height of the protruding portion from a sum of thicknesses of the first electrode and of the electrically insulating layer is less than a sum of thicknesses of the submount, the laser diode element, and the feed structure.

4. The semiconductor laser module according to claim 1, wherein the feed structure is an electrically conductive ribbon having a corrugated shape.

5. The semiconductor laser module according to claim 4, wherein the electrically conductive ribbon having a corrugated shape is fixed to the second electrode in a bonding portion of a peak portion of the electrically conductive ribbon having a corrugated shape.

6. The semiconductor laser module according to claim 5, wherein no part of a peak portion on a side nearer to the laser diode element, of the electrically conductive ribbon having a corrugated shape, is separated apart from the laser diode element.

7. The semiconductor laser module according to claim 1, further comprising:
a manifold to support the heat sink, wherein
the manifold and the heat sink include therein a water channel for circulating cooling water.

8. (canceled)

9. A laser machining apparatus comprising:
a laser oscillator including a plurality of the semiconductor laser modules according to claim 1, to couple the laser beams emitted from the plurality of semiconductor laser modules and to emit a laser beam generated by coupling;
an optical fiber to transmit the laser beam generated by coupling and emitted from the laser oscillator; and
a machining head to collect the laser beam generated by coupling from the optical fiber, and to emit a laser beam collected, to a workpiece.

10. A laser machining apparatus comprising:
a laser oscillator including a plurality of the semiconductor laser modules according to claim 2 to couple the laser beams emitted from the plurality of semiconductor laser modules and to emit a laser beam generated by coupling;
an optical fiber to transmit the laser beam generated by coupling and emitted from the laser oscillator, and
a machining head to collect the laser beam generated by coupling from the optical fiber, and to emit a laser beam collected, to a workpiece.

11. A laser machining apparatus comprising:
a laser oscillator including a plurality of the semiconductor laser modules according to claim 3 to couple the laser beams emitted from the plurality of semiconductor laser modules and to emit a laser beam generated by coupling;
an optical fiber to transmit the laser beam generated by coupling and emitted from the laser oscillator; and
a machining head to collect the laser beam generated by coupling from the optical fiber, and to emit a laser beam collected, to a workpiece.

12. A laser machining apparatus comprising:
a laser oscillator including a plurality of the semiconductor laser modules according to claim 4 to couple the laser beams emitted from the plurality of semiconductor laser modules and to emit a laser beam generated by coupling;
an optical fiber to transmit the laser beam generated by coupling and emitted from the laser oscillator; and
a machining head to collect the laser beam generated by coupling from the optical fiber, and to emit a laser beam collected, to a workpiece.

13. A laser machining apparatus comprising:
a laser oscillator including a plurality of the semiconductor laser modules according to claim 5 to couple the laser beams emitted from the plurality of semiconductor laser modules and to emit a laser beam generated by coupling;
an optical fiber to transmit the laser beam generated by coupling and emitted from the laser oscillator; and
a machining head to collect the laser beam generated by coupling from the optical fiber, and to emit a laser beam collected, to a workpiece.

14. A laser machining apparatus comprising:
a laser oscillator including a plurality of the semiconductor laser modules according to claim 6 to couple the laser beams emitted from the plurality of semiconductor laser modules and to emit a laser beam generated by coupling;
an optical fiber to transmit the laser beam generated by coupling and emitted from the laser oscillator; and
a machining head to collect the laser beam generated by coupling from the optical fiber, and to emit a laser beam collected, to a workpiece.

15. A laser machining apparatus comprising:
a laser oscillator including a plurality of the semiconductor laser modules according to claim 7 to couple the laser beams emitted from the plurality of semiconductor laser modules and to emit a laser beam generated by coupling;
an optical fiber to transmit the laser beam generated by coupling and emitted from the laser oscillator, and
a machining head to collect the laser beam generated by coupling from the optical fiber, and to emit a laser beam collected, to a workpiece.
